(19) United States
(12) Patent Application Publication
(10) Pub. No.: US 2024/0332033 A1
(43) Pub. Date: Oct. 3, 2024

(54) METHOD OF MANUFACTURING SEMICONDUCTOR DEVICES, CORRESPONDING SEMICONDUCTOR DEVICE AND MOUNTING ASSEMBLY

(71) Applicant: STMicroelectronics International N.V., Geneva (CH)

(72) Inventors: Michele DERAI, Milano (IT); Guendalina CATALANO, Milano (IT)

(73) Assignee: STMicroelectronics International N.V., Geneva (CH)

(21) Appl. No.: 18/614,936

(22) Filed: Mar. 25, 2024

(30) Foreign Application Priority Data
Mar. 29, 2023 (IT) 102023000005985

(51) Int. Cl. H01L 21/56; H01L 21/78; H01L 23/00; H01L 23/31

(52) U.S. Cl. CPC H01L 21/561; H01L 21/78; H01L 23/3171; H01L 24/03; H01L 24/05; H01L 24/11; H01L 24/13; H01L 24/16; H01L 24/94; H01L 24/04; H01L 2224/0345; H01L 2224/03912; H01L 2224/0401; H01L 2224/05022; H01L 2224/05147; H01L 2224/05562; H01L 2224/05572; H01L 2224/05582; H01L 2224/05647; H01L 2224/05666; H01L 2224/11462; H01L 2224/11823; H01L 2224/11825; H01L 2224/13021; H01L 2224/13147; H01L 2224/13562; H01L 2224/13582; H01L 2224/13583; H01L 2224/13644; H01L 2224/13655; H01L 2224/13664; H01L 2224/16227; H01L 2224/94

(57) ABSTRACT

A “package-less” integrated circuit semiconductor device is produced by laminating first and second insulating films on opposed first and second surfaces of a semiconductor wafer having semiconductor dice integrated therein. Electrically conductive formations towards die pads of the semiconductor dice are provided in vias to the semiconductor wafer opened through the first insulating film laminated on the first surface of the semiconductor wafer. The semiconductor wafer provided with these electrically conductive formations is singulated at separation lines between neighboring semiconductor dice to produce individual semiconductor devices. Each device has: opposed first and second device surfaces having protective portions of the first and second insulating films laminated thereon, and side surfaces extending between the opposed first and second device surfaces, these side surfaces being left uncovered by the first and second insulating films.

### PRIORITY CLAIM

This application claims the priority benefit of Italian Application for U.S. Pat. No. 10,202,3000005985 filed on Mar. 29, 2023, the content of which is hereby incorporated by reference in its entirety to the maximum extent allowable by law.

### TECHNICAL FIELD

The description relates to manufacturing semiconductor devices.

Solutions as described herein can be applied to power (integrated circuit) semiconductor devices for automotive or consumer products, for instance.

### BACKGROUND

Various manufacturing methods exist for producing devices for the automotive and/or consumer market.

Desirable qualities of such manufacturing methods include: low production costs, simplicity of the manufacturing process and package size reduction.

A conventional approach that aims at reducing package size is the so-called wafer level chip scale packaging (WLCSP). This approach involves (solder) ball mounting of the final device on a substrate like a printed circuit board (PCB). It is recognized, however, that ball mounting on the package is not a simple assembly step.

Another conventional, and extensively applied, approach is based on the so-called quad flat no leads (QFN) package which is based on the use of a substrate (e.g., a leadframe).

Substrates for use in QFN packaging need an ad-hoc design, that is, depending on the particular device design, and such customized leadframes may involve high costs.

Moreover, conventional approaches are based on wires interconnections which are observed to introduce undesired resistances thus reducing electrical performance of the device. By way of background, the following documents, which are incorporated herein by reference:

C-H Chien, et al.: “Glass 3D Solenoid Inductors IPD Substrate Manufacturing Assembly and Characterization”, International Symposium on Microelectronics, 1 Oct. 2016; 2016 (1): 000013-000017;

N. Kumbhat, et al.: “Chip-last fan-out package with embedded power ICs in ultra-thin laminates” Proceedings-Electronic Components and Technology Conference, 1372-1377; and

U.S. Pat. Nos. 9,502,336 and 10,636,734;

are exemplary of various recent advances in manufacturing methods of semiconductor devices aiming at achieving low production costs, simplicity of the manufacturing process and package size reduction.

There is a need in the art for solutions which aim at addressing the issues discussed in the foregoing.

### SUMMARY

One or more embodiments relate to a method.

One or more embodiments relate to a corresponding (integrated circuit) semiconductor device.

One or more embodiments relate to a corresponding mounting assembly (namely a semiconductor device mounted on a support member such as a printed circuit board-PCB).

Solutions as described herein propose a simple and cost-effective manufacturing method of semiconductor device aiming at reducing the size of the final package.

In solutions as described herein the manufacturing process may be carried out entirely at wafer level.

In solutions as described herein external metallic pads are finished with a solderable layer facilitating final mounting on a substrate.

In solutions as described herein, wire interconnects are advantageously replaced with direct metallic interconnects provided via electroplating process.

Solutions as described herein may also be used to provide a final device with wettable flanks.

### BRIEF DESCRIPTION OF THE DRAWINGS

One or more embodiments will now be described, by way of example only, with reference to the annexed figures, wherein:

FIGS. 1A to 1J are a sequence of steps illustrating a conventional manufacturing process of semiconductor devices;

FIGS. 2A to 2K are exemplary of possible sequence of steps in implementing embodiments of the present description;

FIG. 3 is a cross-sectional view of a device according to embodiments of the present description mounted on a substrate; and

FIGS. 4A to 4C are exemplary of an optional sequence of steps to provide a device as described herein with wettable flanks.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description one or more specific details are illustrated, aimed at providing an in-depth understanding of examples of embodiments of this description. The embodiments may be obtained without one or more of the specific details, or with other methods, components, materials, etc. In other cases, known structures, materials, or operations are not illustrated or described in detail so that certain aspects of embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment” or “in one embodiment” that may be present in one or more points of the present description do not necessarily refer to one and the same embodiment.

Moreover, particular conformations, structures, or characteristics may be combined in any adequate way in one or more embodiments.

The headings/references used herein are provided merely for convenience and hence do not define the extent of protection or the scope of the embodiments.

For simplicity and ease of explanation, throughout this description, and unless the context indicates otherwise, like parts or elements are indicated in the various figures with like reference signs, and a corresponding description will not be repeated for each and every figure. Various manufacturing processes exist that involve concurrent processing of a plurality of (integrated circuit) semiconductor devices.

As mentioned in the foregoing, such conventional approaches may suffer from various drawbacks. For instance, standard wafer level chip scale packaging (WLCSP) involves ball mounting of the final device on the substrate (a printed circuit board (PCB) for example) and providing solder balls to the package is not a simple processing step.

On the other hand, quad flat no leads (QFN) packages do not involve ball mounting as the leadframe may be directly soldered on the PCB: however, providing customized leadframes depending on the device design may involve high production costs.

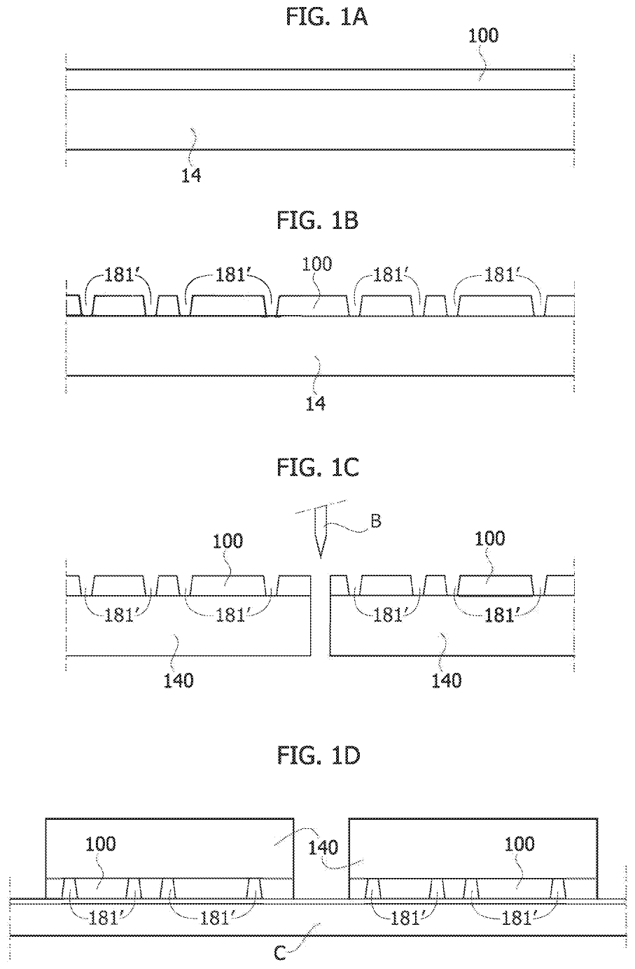

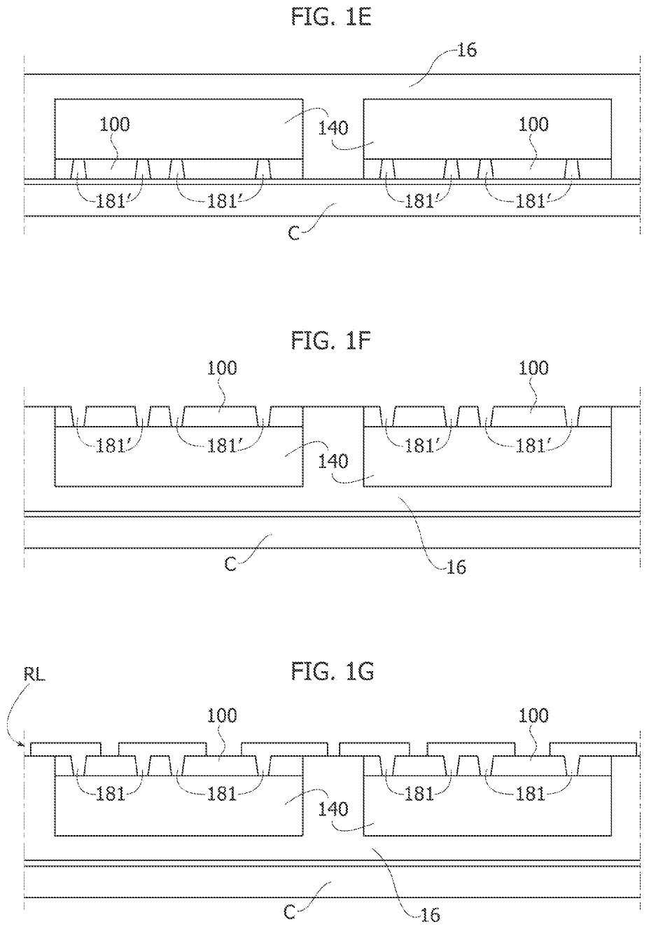

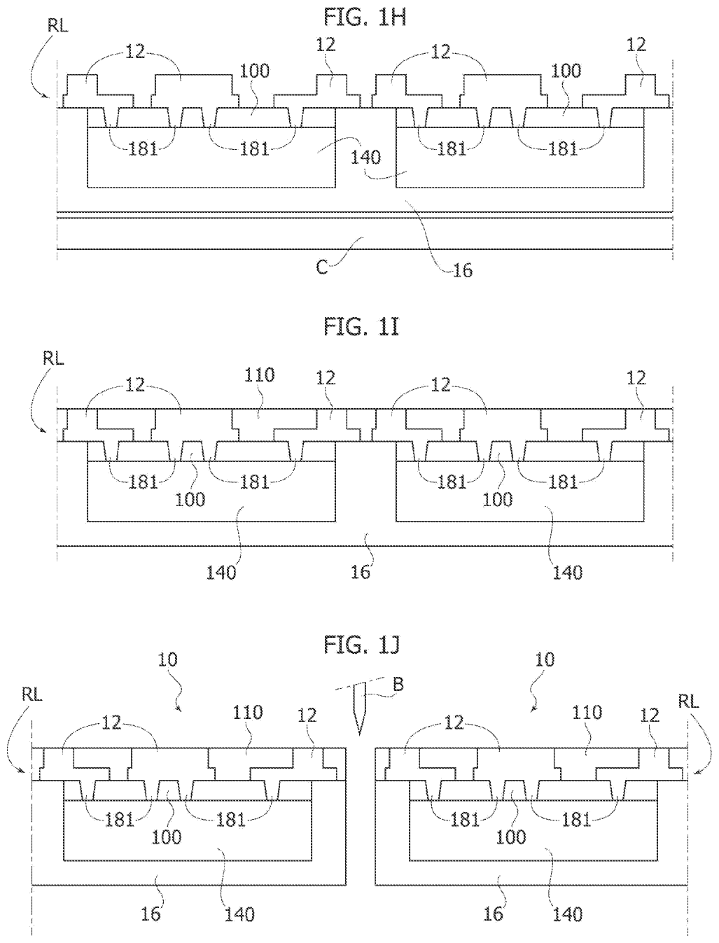

The sequence of FIG. 1A to 1J illustrates a conventional manufacturing process of integrated circuits semiconductor devices.

Such a process is oftentimes referred to as wafer/panel level fan-out packaging.

FIG. 1A is illustrative of an insulating film 100 provided on a semiconductor (silicon, for instance) wafer 14 including integrated circuits, ICs (chips or dice) formed therein, to be possibly processed together. As used throughout this description, the terms chip/s and die/dice are regarded as synonymous.

For simplicity, these circuits (which can be provided in the wafer 14 any manner known to those of skill in the art) are not visible as such in the in the figures.

The film 100 may be, for instance, a film such as an Ajinomoto Build-up Film (ABF) available from Ajinomoto Fine-Techno Co., Inc. of 1-2 Suzuki-cho, Kawasaki-ku, Kawasaki-shi, 210-0801, Japan.

The film 100 can be laminated on a first (active) surface of the wafer 14.

FIG. 1B is illustrative of vias 181′ opened (e.g., via laser beam) to the die pads (not visible in the figures for scale reasons) towards the active surface of the wafer 14.

The wafer 14 can be cut (singulated) into individual dice or chips 140 in a first singulation step, performed via a blade or saw B, for instance, as illustrated in FIG. 1C.

As illustrated in FIG. 1A to 1C the steps discussed are performed at wafer level.

According to a conventional approach, after a first singulation step (as exemplified in FIG. 1C), concurrent processing of a plurality of devices may be carried out after a wafer or a panel has been reconstituted; that is, individual (singulated) dice 140 are arranged on a carrier (wafer or panel shaped) in order to facilitate concurrent processing of the devices.

FIG. 1D is illustrative of individual chips/dice 140 arranged on a first carrier C (a stainless-steel carrier, for instance) having a release tape (not referenced in the figures for simplicity) laminated thereon.

As known to those skilled in the art, such a release tape facilitates detachment and subsequent transfer of the dice 140 from the carrier C.

As illustrated in FIG. 1D, in this step dice 140 may be flipped (that is, turned over so that their active surface faces the carrier C, e.g., with the active surface facing down) and arranged by allowing for a larger spacing between neighboring dice 140 as conventionally done for fan-out wafer (panel) level packaging processes-FOW (P) LP.

As illustrated in the following a fan-out region may be used to provide room for a redistribution layer. The actual size of the “fan-out” region may depend on the desired device design.

FIG. 1E is illustrative of a molding step wherein an insulating molding compound 16 (e.g., an epoxy resin) is molded onto the dice 140 in order to provide a protective plastic package.

As illustrated in FIG. 1F, the wafer/panel (that is, devices 140 kept together by the molding compound 16) is released from the first carrier C and transferred to a second carrier (again indicated with a same reference in the figures for simplicity, being otherwise understood that a different carrier may be used) with the active surface facing up (that is, opposed to the carrier) to facilitate further processing of that surface of the wafer/panel.

FIG. 1G is illustrative of a redistribution layer RL being provided at the active surface of the dice 140 in the panel. As known to those skilled in the art, a redistribution layer (e.g., RL in FIG. 1G) is a metallic (e.g., copper) layer comprising electrically conductive lines/traces used to reroute input/output (I/O) pads of an integrated circuit.

It is noted that vias 181 are now plated with metal (e.g., copper) in order to provide an electrically conductive path from the die pads on the active surface of the dice 140 (not visible in the figures for scale reasons) to the redistribution layer RL.

A redistribution layer RL as exemplified in FIG. 1G may be provided via a photolithographic deposition/growth process, per se conventional in the art. A more detailed description of such a process will be given in the following when describing embodiments of the present description.

A redistribution layer RL as exemplified in FIG. 1G comprises only one layer; in certain cases, several layers may be provided in order to reroute the die pads to the external pads (the studs 12 illustrated in FIGS. 1H to 1J, for instance), each layer being provided via a photolithographic/electroplating deposition process.

FIG. 1H is illustrative of studs/external pads 12 being provided on top of the redistribution layer RL. Studs 12 may be grown via a process similar to the one used to form the redistribution layer RL.

FIG. 1I is illustrative of an insulating film 110 (e.g., another-possibly different-ABF) laminated on the wafer/panel assembly to provide an insulating/protective layer to the devices.

Alternatively, the protective plastic package may be completed via a second molding step of an insulating molding compound such as an epoxy resin, for instance.

Either option (e.g., laminating a sufficiently thick film or applying a second compression molding layer) facilitates encapsulating device traces and studs.

Film (e.g., ABF) lamination may use a laminator to heat a film foil that is as large as an entire panel, which is deployed over the panel via a combined action of vacuum and pressure. After completion of the package, e.g., via insulating film lamination or resin molding, the wafer/panel may be detached from the carrier.

FIG. 1J is illustrative of a second (final) singulation step wherein a panel/wafer is cut (e.g., via sawing) into individual devices 10. Such a second singulation step may be performed after a final plating step of the input/output (I/O) studs 12 for the purpose of enhancing solderability (on a final substrate such a printed circuit board-PCB—for instance).

As described so far, such manufacturing process-oftentimes referred to as fan-out wafer (panel) level packaging (FOW (P) LP)—is conventional in the art, which makes it unnecessary to provide a more detailed description herein.

Otherwise, the sequence of FIGS. 1A to 1J aims at giving only a schematic description of a conventional manufacturing process.

In particular: one or more steps illustrated in FIGS. 1A to 1J can be omitted, performed in a different manner (with other tools, for instance) and/or replaced by other steps; additional steps may be added; one or more steps can be carried out in a sequence different from the sequence illustrated.

Cases exist where a simpler process is desirable. For example, certain products for the automotive or consumer market may benefit from a simplification of the manufacturing process that translates in lower production costs and shorter processing time.

Solutions as described herein aim at providing a simple and cost-effective manufacturing method of semiconductor devices.

In solutions as described herein, the manufacturing process may be carried out entirely at wafer level.

In solutions as described herein, insulating films laminated on opposed surfaces of a wafer replace a conventional plastic package, thus reducing the size of the device and making unnecessary a molding step.

In solutions as described herein, external pads provided on the active surface of the wafer may be finished with a solderable protective layer.

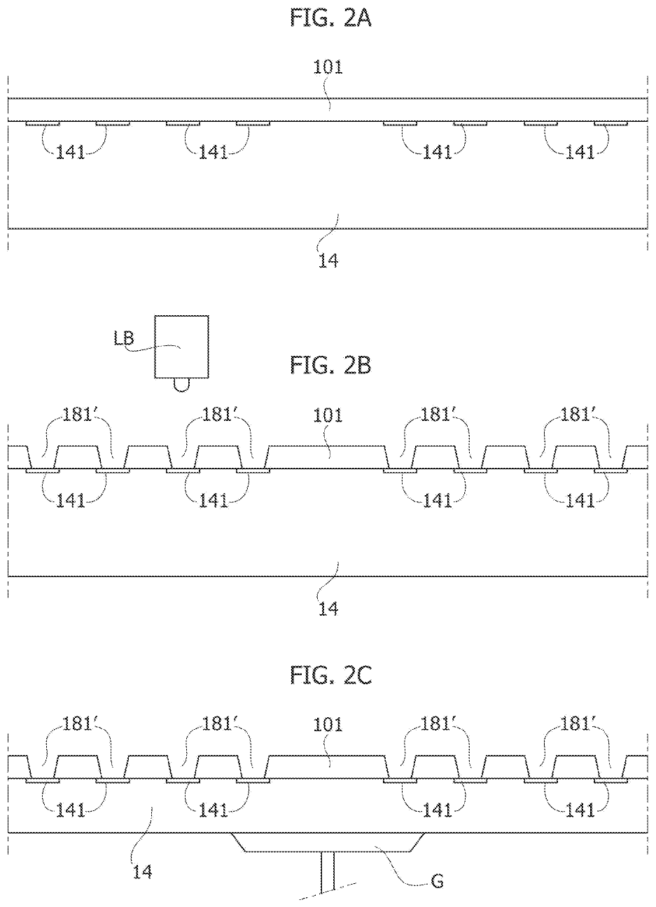

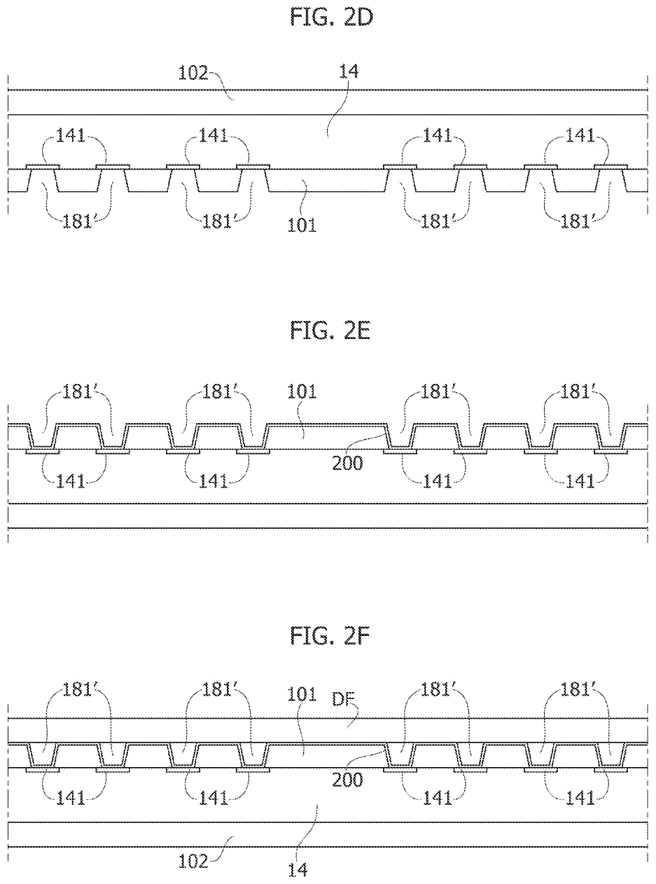

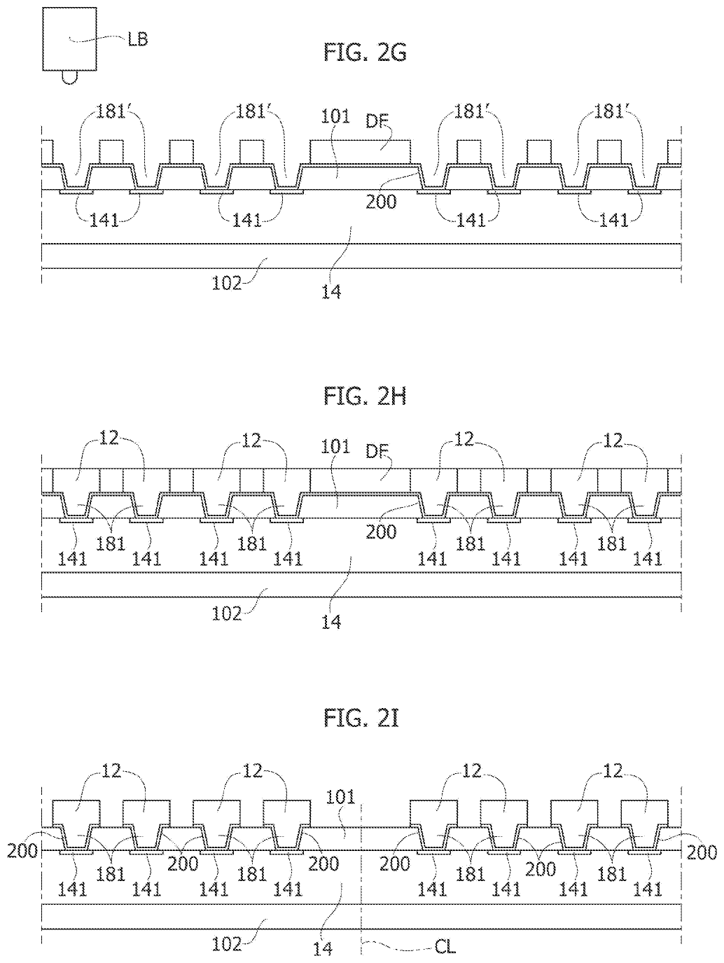

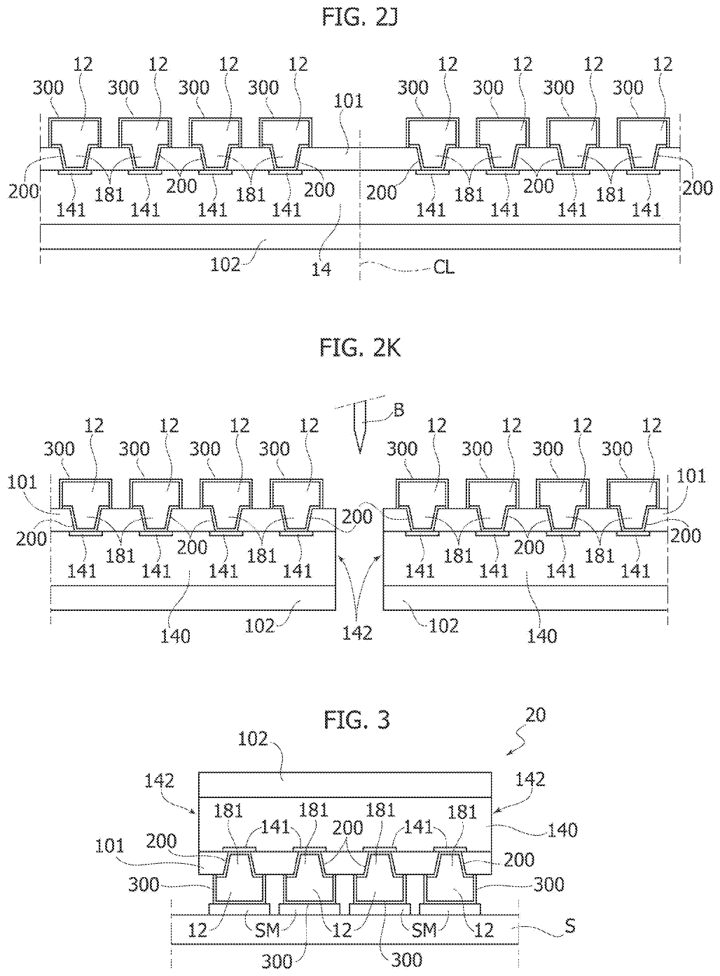

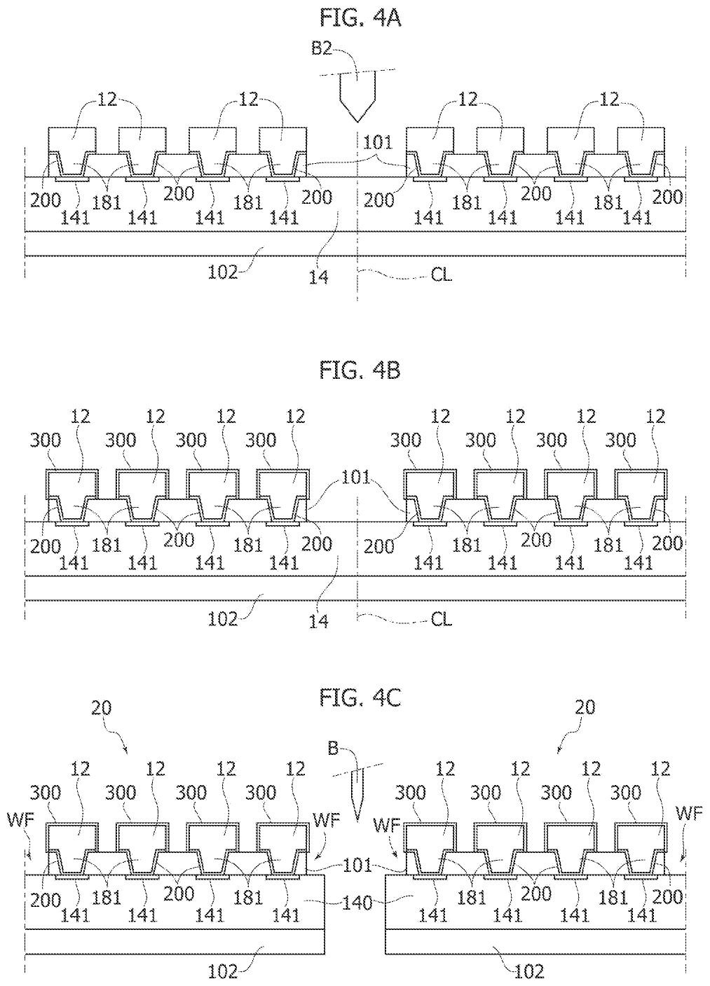

Solutions as described herein in connection with FIGS. 2A to 2K may optionally be modified as exemplified in FIGS. 4A to 4C in order to provide final devices with wettable flanks.

It is otherwise noted that the sequences of FIGS. 2A to 2K and FIGS. 4A to 4C aim at giving only an exemplary representation of a related process.

For instance: one or more steps illustrated in FIGS. 2A to 2K and FIGS. 4A to 4C can be omitted, performed in a different manner (with other tools, for instance) and/or replaced by other steps; additional steps may be added; one or more steps can be carried out in a sequence different from the sequence illustrated.

The representation in FIGS. 2A and 2B is per se identical to the representation in FIGS. 1A and 1B.

FIG. 2A is again illustrative of an insulating film 101 laminated on a first (upper in the figure) surface of a semiconductor (silicon, for instance) wafer 14 having integrated circuits, ICs, already formed therein in a manner known to those of skill in the art so that these can be concurrently processed.

Again, the film 101 may be, for instance, a film such as an Ajinomoto Build-up Film (ABF), already mentioned in the foregoing.

FIG. 2B is illustrative of opening of vias 181′ to the die pads 141 located at the first active surface of the wafer 14. As indicated by LB, vias 181′ can be provided via laser ablation at desired locations of the insulating film 101.

However, contrary to FIG. 1C, the assembly of FIG. 2B is not “singulated” and is in fact subjected to various types of processing.

For instance, a grinding step as illustrated by G in FIG. 2C may advantageously be performed in order to reduce the thickness of the wafer 14. This step may be useful in reducing in as much as possible the thickness of the final device.

FIG. 2D is illustrative of a second insulating film 102 laminated on the second surface of the wafer 14, opposed to the surface onto which the film 101 was laminated.

For instance, the second insulating film 102 may again be a film such as an Ajinomoto Build-up Film (ABF), already mentioned in the foregoing, but not necessarily of the same type of the first insulating film 101. For example, a different thickness and/or chemical composition may be envisaged for the second insulating film 102.

For instance, the film 102 may differ from the film 101 and/or either film 101, 102 can be a mold film used to protect an (e.g., back) side in a semiconductor wafer.

Different types of ABF/mold film can be used as desired, e.g., according to specific requirements.

As illustrated, applying the second insulating film 102 on the second surface of the wafer 14 may involve turning over the wafer 14 as this may facilitate the related processing.

However implemented, laminating insulating films (e.g., 101 and 102) on both surfaces of the wafer 14 may facilitate providing a protection to the wafer 14 (and thus the ICs formed therein) without using of an, e.g., plastics, package (as provided by the molding compound illustrated in FIG. 1J, for instance) which involves an additional molding step.

Replacing a conventional package with insulating films (e.g., 101 and 102) may be advantageous both in terms of simplicity of the assembly flow and final package size.

As it will be described in the following, after the singulation (illustrated in FIGS. 2K and 4C) of the wafer assembly, final devices 20 produced according to embodiments of the present description may have the semiconductor material of the wafer 14 (e.g., silicon) exposed on their lateral surfaces (or, in any case, left uncovered by the films 101 and 102).

That is, as illustrated herein, singulating (e.g., via a blade B) the semiconductor wafer 14 produces individual semiconductor devices 20 each having opposed first and second device surfaces (corresponding to the opposed surfaces of the wafer 14) having respective portions of the first and second insulating films 101, 102 laminated thereon as well as side surfaces 142 extending between the opposed first and second device surfaces.

It has been observed that laminating insulating films 101, 102 (only) on the opposed first and second surfaces of the wafer 14 (and after singulation, of the final device) facilitates providing adequate protection to the ICs comprised in the wafer 14 (the device 20) while, at the same time, facilitating a reduced package dimension.

FIGS. 2E to 21 illustrate steps that can be performed on the assembly of FIG. 2D having insulating films 101, 102 laminated on both its opposed surfaces.

FIG. 2E is illustrative of a (photolithographic) process providing external pads to the ICs in the wafer 14 by growing metallic (e.g., copper) material on the first (active) surface of the wafer 14.

FIG. 2E is illustrative of a growth/deposition (e.g., via sputtering) of a seed layer 200 on the first insulating film 101. As known to those skilled in the art, growing such a seed layer 200 may comprise, for instance, a first deposition of a Ti layer followed by the deposition of a Cu layer.

A seed layer (e.g., 200) facilitates growing additional metallic (e.g., copper) material via electrolytic/galvanic plating, for instance.

FIG. 2F is illustrative of photoresist material DF provided on the first (active) surface of the wafer 14, that is, on the seed layer 200 thereon.

A dry film DF may be advantageously used for this step; the thickness of the dry film DF may be chosen according to device design in as much as the “height” of the external pads (illustrated in FIG. 2I and referenced therein with the reference 12) is determined by the thickness of the dry film DF.

For instance, the thickness of the dry film DF can be selected taking into account a desired thickness (height) for, e.g., copper pads that are grown therein.

FIG. 2G is illustrative of the dry film DF being patterned via laser direct imaging (LDI) and subsequently developed in order to transfer a desired pattern to the dry film DF.

It is noted that such patterning may advantageously replace providing (e.g., via back end of the line or BEOL processes) “redistribution” layer as used in certain conventional device designs to redistribute the pads of the (IC) dice formed in the wafer 14.

In solutions as described herein, such a redistribution layer (like the redistribution layer RL illustrated in FIG. 1G) can be avoided, with the pattern transferred to the dry film DF (illustrated in FIG. 2G) comprising simply openings located at the pads of the dice in the wafer 14, and no metallic traces or lines.

Consequently, as illustrated in FIG. 2G, the pattern transferred (via a laser beam, LB) to the dry film DF may consist (only) of holes/openings located at vias openings 181′.

FIG. 2H is illustrative of electrically conductive (e.g., metal such as copper) material deposited/grown on the patterned dry film DF, facilitated by the seed layer 200. Such a plating step may be performed, for example, via electrolytic/galvanic plating.

Studs or (external) pads 12 are formed at vias 181 of the first insulating film 101; openings 181′ (as illustrated and referenced in FIG. 2G, for instance) of the first insulating film 101 are now plated with conductive material, e.g., copper.

These are referenced with the reference 181 (no accent any longer) thus providing electrical coupling between the pads of the ICs on the first (active) surface of the wafer 14 and the studs 12.

Dry film DF is stripped and the seed layer 200 etched away (where it is not covered with the metallic material of the vias 181 and studs 12) resulting in the assembly illustrated in FIG. 2I.

FIG. 2J is illustrative of a pads/studs 12 finishing steps wherein an additional layer 300 can be deposited on pads 12 to enhance solderability.

This layer may comprise a Ni layer (e.g., provided via an electroless plating process) and an Au layer (e.g., provided via immersion in a gold salts bath) resulting in what is generally referred to as electroless-nickel immersion-gold (ENIG) finishing.

ENIG finishing, per se conventional in the art, enhances solderability of external pads 12 and provides a protective layer countering oxidation of external pads 12.

Alternatively, the metallic layer 300 may be an electroless Ni-electroless Pd-immersion Au (ENEPIG) finishing with the same purpose as the ENIG layer (that is, enhanced solderability and protection from oxidation).

FIG. 2K illustrates a singulation step wherein the wafer 14 is finally cut (portioned) into individual devices 20 via sawing with a blade B, for instance.

Individual devices 20 as illustrated in FIG. 2K comprise respective portions of the semiconductor (e.g., silicon) wafer 14 each having at least one semiconductor dice integrated therein.

A final device 20 as illustrated in FIG. 3 may be mounted on a substrate S such as a printed circuit board (PCB) via solder material SM.

To summarize, a device 20 as illustrated in FIG. 3 comprises first and second insulating films 101, 102 laminated on opposed first and second surfaces of a portion of a semiconductor wafer 14. The device has integrated therein one or more semiconductor dice 140 having die pads 141 at the first surface.

Electrically conductive formations 12, 181 are provided towards the die pads 141 including, e.g., metal such as copper (Cu).

The electrically conductive formations 12, 181 extending in the vias 181′ opened (e.g., via laser beam LB) in the first insulating film 101 laminated on the first surface.

A device 20 as illustrated in FIG. 3 comprises side surfaces 142 extending between the opposed first and second surfaces.

These side surfaces 142 are left uncovered by the first and second insulating films 101, 102.

As illustrated in FIG. 3, the final devices 20 may have semiconducting material of the wafer 14 (e.g., silicon) exposed on their lateral surfaces 142. For instance, if not covered otherwise, the semiconductor die 140 is visible on the side faces 142 of the device 20, insofar as this is “covered” by the films 101, 102 laminated (only) on its first and second opposed surfaces.

That is, as illustrated herein, singulating (e.g., via a blade B) the semiconductor wafer 14 produces individual semiconductor devices 20 each having opposed first and second device surfaces (corresponding to the opposed surfaces of the wafer 14) having respective portions of the first and second insulating films 101, 102 laminated thereon as well as side surfaces 142 extending between the opposed first and second device surfaces.

As visible, the side surfaces 142 are left uncovered by the first and second insulating films 101 and 102. As further visible, the individual semiconductor device 20 is not encapsulated by a package material other than said first and second insulating films.

As mentioned, laminating insulating films 101, 102 on (only) the opposed first and second surfaces of the device 20 has been observed to be able to provide an adequate protection to the ICs comprised the device (in the absence of other package material) while, at the same time, maintaining reduced package dimension.

This primarily in comparison to conventional arrangements where a molding compound (e.g., an epoxy resin) is molded onto the device to complete the plastic package thereof, thus covering also the side surfaces (see FIG. 1J, for instance).

The external pads 12 may be advantageously finished with a ENIG or ENEPIG layer for enhanced solderability and protection (against oxidation, for instance).

The metallic formations (vias 181 and pads/studs 12) may be provided with a photolithographic plating process (as discussed in the foregoing) possibly leaving a seed layer 200 beneath the metallic formations 181, 12.

The sequence of FIGS. 4A to 4C illustrates optional processing steps aiming at providing a device 20 with wettable flanks.

As known to those skilled in the art, wettable flanks are a desirable feature which facilitate the formation of a solder meniscus when mounting (via solder material) a device on the final substrate (e.g., a PCB).

In addition to being beneficial for the integrity/reliability of the solder joint, a solder meniscus facilitates visual checking and testing of solder joints via automated optical inspection (AOI).

FIG. 4A illustrates a partial cut performed (via a first blade B2, for instance) on a semiconductor wafer 14 having metallic formations 181, 12 formed on the first/active surface thereof. That is, FIG. 4A results from performing a partial cut on a processed wafer 14 as illustrated in FIG. 2I, the sequence of FIGS. 4A to 4C representing an alternative sequence of steps.

The partial cut is performed at the cutting lines CL of the final singulation cut (illustrated in FIG. 4C) in order to expose (at the periphery of the device) the lateral surface of pads 12 that are located at the periphery of the device.

FIG. 4B is illustrative of a pads/studs 12 finishing steps wherein a ENIG or ENEPIG layer 300 is deposited on pads 12 to enhance solderability and provide protection from oxidation. This step is similar to what is illustrated in FIG. 2J.

FIG. 4C illustrates a final singulation step wherein the wafer 14 is cut (e.g., via sawing with a second blade B) into singulated devices 20.

A second blade B different from the first blade B2 may be used to perform the singulation step illustrated; for example, a second blade B thinner than the first blade B2 may be used, this resulting in the “step” (a sort of undercut) illustrated in FIG. 4C and referred therein with the reference WF.

The claims are an integral part of the technical teaching provided in respect of the embodiments.

Without prejudice to the underlying principles, the details and embodiments may vary, even significantly, with respect to what has been described by way of example only without departing from the extent of protection. The extent of protection is determined by the annexed claims.

1. A method, comprising:
laminating first and second insulating films on opposed first and second surfaces, respectively, of a semiconductor wafer having a plurality of semiconductor dice integrated therein, the semiconductor dice having die pads at the first surface;
opening vias to the semiconductor wafer through the first insulating film laminated on the first surface of the semiconductor wafer;
providing electrically conductive formations towards said die pads, the electrically conductive formations extending in said vias; and
singulating the semiconductor wafer provided with said electrically conductive formations at separation lines between neighboring semiconductor dice in the plurality of semiconductor dice;
wherein singulating the semiconductor wafer produces individual semiconductor devices each having opposed first and second device surfaces with portions of the first and second insulating films laminated thereon as well as side surfaces of the singulted semiconductor wafer extending between the opposed first and second device surfaces, the side surfaces left uncovered by said first and second insulating films.

2. The method of claim 1, wherein providing the electrically conductive formations towards said die pads comprises growing electrically conductive material at the vias to the semiconductor wafer opened through the first insulating film laminated on the first surface of the semiconductor wafer.

3. The method of claim 2, wherein providing the electrically conductive formations towards said die pads comprises providing contact pads on the first insulating film laminated on the first surface of the semiconductor wafer.

4. The method of claim 3, wherein providing contact pads on the first insulating film laminated on the first surface of the semiconductor wafer comprises performing an electroplating deposition.

5. The method of claim 3, comprising finishing the contact pads with a solderable protective electroless-nickel immersion-gold (ENIG) layer or electroless Ni-electroless Pd-immersion Au (ENEPIG) layer.

6. The method of claim 1, wherein one or both of the first and second insulating films is an Ajinomoto-Build-Up film.

7. The method of claim 1, comprising:
providing selected ones of said electrically conductive formations towards said die pads at said separation lines between neighboring semiconductor dice;
wherein singulating the semiconductor wafer at said separation lines between neighboring semiconductor dice comprises partially cutting the semiconductor wafer starting from the first surface of the semiconductor wafer having the first insulating film laminated thereon, wherein wettable flanks are formed at said selected ones of said electrically conductive formations in response to said partial cutting.

8. The method of claim 1, wherein the side surfaces left uncovered by said first and second insulating films are made of semiconductor material of said wafer.

9. The method of claim 1, wherein each individual semiconductor device is not encapsulated by a package material other than said first and second insulating films.

10. A semiconductor device, comprising:
first and second insulating films laminated on opposed first and second surfaces, respectively, of a portion of semiconductor wafer having integrated therein at least one semiconductor die having die pads at the first surface;
electrically conductive formations extending in vias opened in the first insulating film laminated on the first surface to connect with said die pads; and
wherein side surfaces of the at least one semiconductor die extend between the opposed first and second surfaces, with the side surfaces left uncovered by said first and second insulating films.

11. The semiconductor device of claim 10, wherein selected ones of said electrically conductive formations have wettable flanks.

12. The semiconductor device of claim 10, further comprising contact pads on the first insulating film.

13. The semiconductor device of claim 12, further comprising a solderable protective finishing layer on the contact pads comprising one of an electroless-nickel immersion-gold (ENIG) layer or an electroless Ni-electroless Pd-immersion Au (ENEPIG) layer.

14. The semiconductor device of claim 10, wherein one or both of the first and second insulating films is an Ajinomoto-Build-Up film.

15. The semiconductor device of claim 10, wherein the side surfaces left uncovered by said first and second insulating films are made of semiconductor material of said wafer.

16. The semiconductor device of claim 10, wherein the semiconductor device is not encapsulated by a package material other than said first and second insulating films.

17. An assembly, comprising:
a semiconductor device support member; and
the semiconductor device according to claim 10, wherein the semiconductor device electrically is coupled to the semiconductor device support member via said electrically conductive formations.
